(19) United States
(12) Patent Application Publication
(10) Pub. No.: US 2019/0186003 A1
(43) Pub. Date: Jun. 20, 2019

(54) AMPOULE VAPORIZER AND VESSEL

(71) Applicant: ENTEGRIS, INC., Billerica, MA (US)

(72) Inventors: David James ELDRIDGE, Liberty Hill, TX (US); John M. CLEARY, Monroe, CT (US); Jacob THOMAS, Leander, TX (US); Scott L. BATTLE, Cedar Park, TX (US); Thomas CHATTERTON, Round Rock, TX (US); John GREGG, Marble Falls, TX (US); Bryan C. HENDRIX, Danbury, CT (US); Thomas H. BAUM, New Fairfield, CT (US)

(21) Appl. No.: 16/214,516

(22) Filed: Dec. 10, 2018

Related U.S. Application Data
(60) Provisional application No. 62/598,870, filed on Dec. 14, 2017.

(51) Int. Cl. C23C 16/448; C23C 14/48

(52) U.S. Cl. CPC C23C 16/4481; C23C 14/48

(57) ABSTRACT

The invention is directed to a vaporizer or ampoule assembly with an improved vaporizer vessel body and support tray assembly configuration located therein that together increase the vaporizable material utilization and uniformity.

### CROSS-REFERENCE TO RELATED APPLICATIONS

This application claims the benefit under 35 USC 119 of U.S. Provisional Patent Application No. 62/598,870, filed Dec. 14, 2017, the disclosure of which is hereby incorporated herein by reference in its entirety for all purposes.

### FIELD OF THE INVENTION

The present disclosure relates generally to vaporizers useful in volatilizing solid precursors to provide precursor vapor to a precursor vapor-utilizing process system such as a vapor deposition chamber or an ion implanter and more specifically to support tray assemblies located within vaporizer vessels.

### BACKGROUND

In the use of solid-phase precursors to supply precursor vapor for vapor-utilizing applications, a wide variety of vaporizers have been used. Such vaporizers may comprise a vessel and cover defining an enclosed interior volume in which a solid phase precursor may be stored and subsequently subjected to volatilization conditions to effect sublimation or vaporization of the solid phase precursor to produce precursor vapor. For such purpose, the vaporizer vessel or vessel body may be fabricated of a heat-conductive material and heated to cause the volatilization of the precursor on the support tray and/or a heated carrier gas may be flowed through the vessel to create a mass transfer gradient resulting in entrainment of precursor vapor from the solid source precursor material.

As the market demands a more uniform delivery of precursor material with greater utilization levels from the current levels of about 50% of utilization, manufacturers have to respond with vessel bodies and tray assembly combinations that vary in size, depending on the application, to address these demands. However, simply increasing the size of ampoules or vaporizers may lead to installation and refilling challenges for the users that might not be offset by the benefits of having more precursor material available. Therefore, there is a need in the semiconductor industry to improve precursor delivery uniformity for longer periods of time.

### SUMMARY

New applications in the industry require higher delivery rates and more complete utilization of the high value precursors. Increased demands on vaporizer performance have identified shortcomings in the current vaporizer designs using traditional vessel body and support tray assemblies. It would be advantageous to improve current precursor vaporization systems that utilize a vaporizer vessel body with supporting trays without substantially increasing material, energy and labor costs to the end user.

In one example embodiment of a vaporizer or ampoule system, there is provided a vaporizer assembly for vaporizing and delivering vaporized source material that includes a multiple-vessel body assembly including at least a first and a second longitudinally attached vessel bodies having a common longitudinal axis and which define an interior volume of the multiple-vessel body assembly, each of the vessel bodies having an interior volume defined by a sidewall and a vessel body rim opening, each of the vessel bodies having an interior diameter of the vessel body and having an interior sidewall surface. The vaporizer system also includes a base member disposed under and closing a bottom opening of the first vessel body and a lid member disposed on the rim opening of the second vessel body, the second vessel body disposed on the rim opening of the first vessel body. The system further includes a gas inlet and a gas outlet arranged in fluid communication with the interior volume of the multiple-vessel body assembly, the gas inlet being adapted to supply a first gas to the interior volume of the multiple -vessel body assembly. The system also includes a plurality of vented support trays with tray circumferential sidewalls disposed within the interior volume and in contact with interior diameter of the multiple-vessel body assembly, the plurality of vented support trays including a first set of trays disposed within the first vessel body and under a second set of trays that are disposed within the second vessel body, wherein each of the first set of trays have a first tray sidewall height greater than a second tray sidewall height of the second set of trays, the plurality of the support trays adapted to support a vaporizable source material in the flow path extending between the gas inlet and the gas outlet.

In a related embodiment, the first vessel body has a longitudinal height greater than the longitudinal height of the second vessel body. In another embodiment, a first longitudinal height of the first vessel body is equal to the longitudinal height of the second vessel body. In yet another related embodiment, the second vessel body includes a lower base rim configured to mate with the upper rim opening of the first vessel body. In another embodiment, the first tray sidewall height is less than the second tray sidewall height.

In a related example embodiment of a vaporizer system, a number of the first set of support trays equals the number of the second set of support trays. In another example embodiment, the number of first set of support trays is greater than the number of the second set of support trays. In yet another example embodiment, the height of each of the first set of support trays is about 3 to about 4 times the height of each of the second set of support trays. In another example embodiment, the vaporizer assembly includes support trays that have an anti -corrosion coating selected from the group consisting of metal oxides, metal nitrides, metal carbides, and combinations of these films layered together. The chemical delivery system is configured to heat the bulk container to sublimate the precursor thus converting the precursor into vapor form. The chemical delivery system is also configured to heat the first conduit to maintain the precursor in vapor form.

In a related embodiment, there is provided a vaporizer assembly for vaporizing and delivering vaporized source material that includes a vessel body having an interior volume defined by a sidewall, a vessel body rim opening and an interior sidewall surface. The vaporizer assembly also includes a base member disposed under and closing a bottom opening of the first vessel body and a lid member disposed on the rim opening of the vessel body and a gas inlet and a gas outlet arranged in fluid communication with the interior volume of the vessel body, the gas inlet being adapted to supply a first gas to the interior volume of the vessel body. The vaporizer assembly further includes a plurality of vented support trays with tray circumferential sidewalls disposed within the interior volume and in contact with interior diameter of the vessel body, the plurality of vented support trays including a first set of trays disposed within the first vessel body and under a second set of trays that are disposed within the vessel body, wherein each of the first set of trays have a first tray sidewall height greater than a second tray sidewall height of the second set of trays, the plurality of the support trays adapted to support a vaporizable source material in the flow path extending between the gas inlet and the gas outlet.

The novel features of the various embodiments the invention itself, both as to its construction and its method of operation, together with additional advantages thereof, will be best understood from the following description of specific embodiments when read in connection with the accompanying drawings.

### BRIEF DESCRIPTION OF THE DRAWINGS

FIG. 1A illustrates a prior art vaporizer vessel including an outer shell body enclosing one or more support trays.

FIGS. 1B and 1C illustrate a top view and a side cutaway view of an embodiment of a vaporizer vessel enclosing one or more support trays.

FIGS. 2A-2D illustrate a perspective view, an exploded view, a side view and a top view of a vaporizer vessel assembly including a set of support trays inside a vessel body or base according to an example embodiment of the invention.

FIGS. 3A-3C illustrate top, side and perspective views of a support tray for any of the vaporizer vessels described herein according to an example embodiment of the invention.

FIGS. 4A-4D illustrate a perspective view, an exploded view, a side view and a top view of a vaporizer vessel assembly including a set of support trays inside a vessel body or base according to an example embodiment of the invention.

FIGS. 5A-5C illustrate top, side and perspective views of a support tray for any of the vaporizer vessels described herein according to an example embodiment of the invention.

### DESCRIPTION

Following are more detailed descriptions of various related concepts related to, and embodiments of, methods and apparatus according to the present disclosure. It should be appreciated that various aspects of the subject matter introduced above and discussed in greater detail below may be implemented in any of numerous ways, as the subject matter is not limited to any particular manner of implementation. Examples of specific implementations and applications are provided primarily for illustrative purposes.

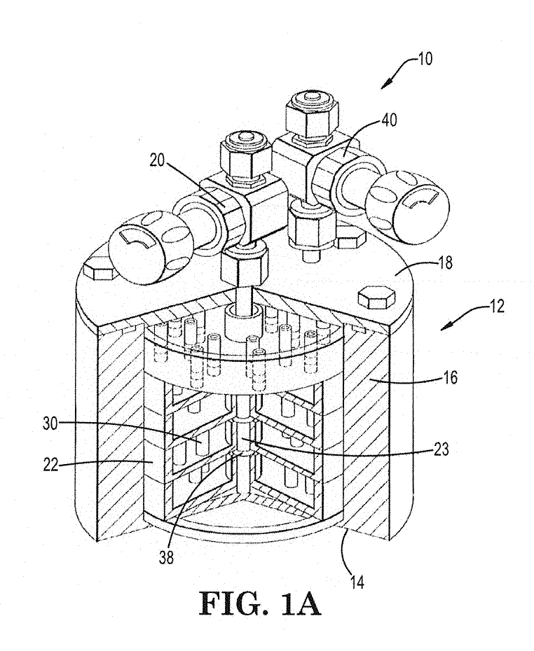

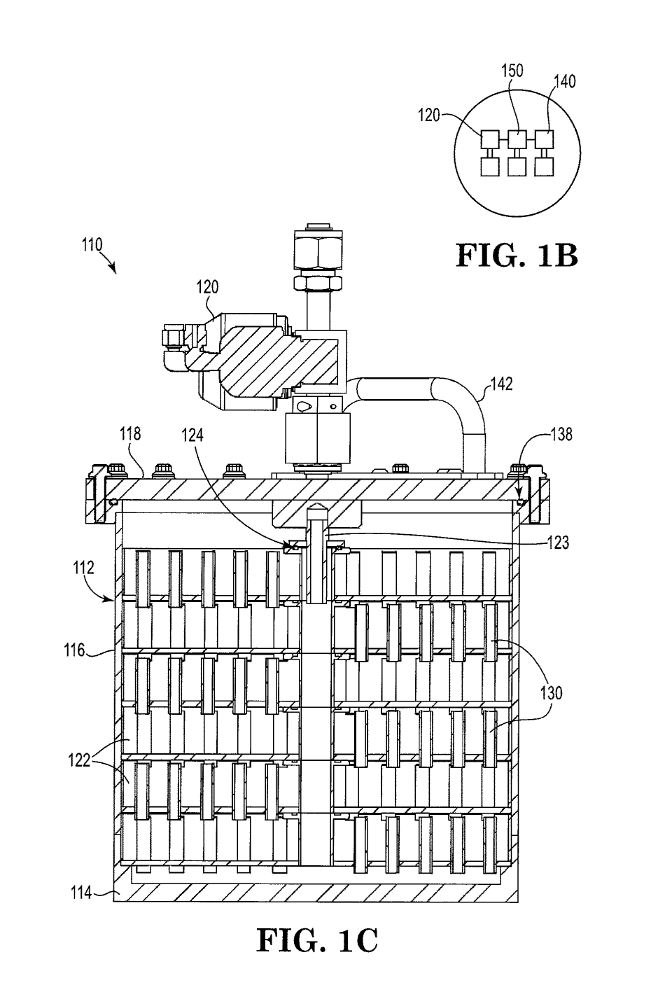

Referring to the Figures, FIG. 1A is perspective view of a prior art vaporizer 10 of a general type. The vaporizer 10 comprises a vessel body 12 fabricated of a suitable heat -conducting material. Vessel body 12 comprises a floor 14 and circumscribing sidewall 16 that together form an interior volume of the vessel. Vessel body 12 can have any shape that facilitates an even flow of carrier gas through the interior volume thereof. In one embodiment, the vessel has a cylindrical shape machined to very close tolerances (e.g., in a range of 1/1000th to 3/1000th of an inch (25.4 μm to 76.2 μm). The vessel includes a lid 18 on which is mounted a carrier gas inlet valve 20 arranged to selectively introduce carrier gas into the interior volume of the vessel, when the valve is open, and a gas outlet valve 40 for dispensing of the vaporized material from the vaporizer vessel. Vaporizer vessel body 12 can be constructed from materials including stainless steel, graphite, silver, silver alloy, copper, copper alloy, aluminum, aluminum alloy, lead, nickel clad, silicon carbide coated graphite, pyrolytic carbon coated graphite, boron nitride, ceramic material, etc., as well as combinations, mixtures and alloys of two or more of such types of material.

Positioned in the internal volume of vessel body 12 is a plurality of vertically stacked support trays 22. The stacked support trays are separable from each other and removable from the vessel body for cleaning and refilling. Positioned within the vessel body is an internal central carrier gas downtube 23 that is connected (welded) to a gas inlet in the lid associated with inlet valve 20 and conveys the carrier gas to the bottom of the internal volume below the lowest tray in the array of vertically stacked trays. In FIG. 1A, central carrier gas downtube 23 passes through a cylindrical collar of each tray that extends through the floor of the tray. In this example, there is included at the cylindrical collar next to downtube 23 a sealing O-ring 38 positioned between successive trays to ensure a leak-proof seal at the juncture of the downtube with the floor of the tray. An additional outer O-ring can also be utilized to seal between trays on the top surface of each tray sidewall. Each of the individual trays 22 has a floor and sidewall to form a tray cavity for placement and support of the source material. The trays are preferably fabricated of a non-reactive heat-conducting material, such as for example stainless steel, silver, silver alloy, copper, copper alloy, aluminum, aluminum alloy, lead, nickel clad, graphite, pyrolytic carbon coated graphite, silicon carbide coated graphite, boron nitride, ceramic material, and combinations, mixtures and composites of two or more of the foregoing.

Referring again to FIG. 1A, the vertically stacked trays are provided with a plurality of protuberances or through-tubes 30 through which the carrier gas flows. The trays hold a solid precursor material for volatilization upon heating thereof. The heating may be carried out with thermal energy being inputted to the vessel body to conductively heat the trays mounted in the vessel body so that the precursor material disposed in the trays is heated sufficiently to volatilize the precursor material. The volatilized precursor then is entrained in the carrier gas flowed through the interior volume of the vaporizer vessel and carried out of the vessel body via outlet 40 in such carrier gas in the dispensing operation. Additionally, or alternatively, to the heating of vaporizer vessel 10 with thermal energy input, the carrier gas itself may be heated to an appropriate temperature to effect or assist in the volatilization of the precursor material within the trays when the carrier gas is contacted with the precursor material.

FIGS. 1B and 1C illustrate a side cutaway view and a top view of another embodiment of a vaporizer vessel 110 enclosing one or more support trays 122. The vaporizer 110 comprises a vessel body 112 fabricated of a suitable heat-conducting material. Vessel body 112 comprises a floor 114 and circumscribing sidewall 116 that together form an interior volume of the vessel. Vessel body 112 can have any shape that facilitates an even flow of carrier gas through the interior volume thereof. In one embodiment, the vessel has a cylindrical shape machined to very close tolerances (e.g., in a range of 1/1000th to 3/1000th of an inch (25.4 μm to 76.2 μm). The vessel includes a lid 118 that fits over vessel body 112 and includes an interposing O-ring 138 to improve the seal between lid 118 and body 112. Lid 118 includes mounted thereon a carrier gas inlet valve 120 arranged to selectively introduce carrier gas into the interior volume of the vessel, when the valve is open, and a gas outlet valve 140 for dispensing of the vaporized material from the vaporizer vessel and a bypass valve 150 for use of purging connections dry after installation and removing residual chemistry to remove the container after use. The bypass valve could also be used to cycle carrier gas flow between the container during deposition and the bypass between wafers or pulses. Vaporizer vessel body 112 can be constructed from materials similar to vessel body 12 described above.

Positioned in the internal volume of vessel body 112 is a plurality of vertically stacked support trays 122. The stacked support trays are separable from each other and removable from the vessel body for cleaning and refilling. Positioned within the vessel body is an internal central carrier gas downtube 123 that is connected (welded) to a gas inlet in the lid associated with inlet valve 120 and conveys the carrier gas to the bottom of the internal volume below the lowest tray in the array of vertically stacked trays and the gas with the precursor material comes up through the vent tubes and exits tube 142 and exits through outlet 140. In FIG. 1C, central carrier gas downtube 123 passes through a cylindrical collar of each tray that extends through the floor of the tray. In this example, there is included at the cylindrical collar next to downtube 123 a cylindrical color or sealing O-ring 124 positioned between successive trays to ensure a leak-proof seal at the juncture of the downtube with the floor of the tray. Alternatively, the O-ring would seal between the carrier gas down tube and the first tray only and the successive trays below are adequately sealed without an O-ring. An additional outer O-ring 138 is utilized to seal between the body or base flange and the lid 118. Each of the individual trays 122 has a floor and sidewall to form a tray cavity for placement and support of the source material. The trays are preferably fabricated of a non-reactive heat-conducting material, such as for example stainless steel, silver, silver alloy, copper, copper alloy, aluminum, aluminum alloy, lead, nickel clad, graphite, pyrolytic carbon coated graphite silicon carbide coated graphite, boron nitride, ceramic material, and combinations, mixtures and composites of two or more of the foregoing.

Referring again to FIGS. 1B and 1C, the vertically stacked trays are provided with a plurality of protuberances or through-tubes 130 through which the carrier gas flows. The trays hold a solid precursor material for volatilization upon heating thereof. The heating may be carried out with thermal energy being inputted to the vessel body to conductively heat the trays mounted in the vessel body so that the precursor material disposed in the trays is heated sufficiently to volatilize the precursor material. The volatilized precursor then is entrained in the carrier gas flowed through the interior volume of the vaporizer vessel and carried out of the vessel body via outlet 40 in such carrier gas in the dispensing operation. Additionally, or alternatively, to the heating of vaporizer vessel 110 with thermal energy input for this and other embodiments described herein, the carrier gas itself may be heated to an appropriate temperature to effect or assist in the volatilization of the precursor material within the trays when the carrier gas is contacted with the precursor material.

Even with the various configurations offered in the prior art to facilitate even and continuous sublimation of precursor materials for semiconductor processing, semiconductor component manufacturers are facing the challenges of increasing semiconductor component processing throughput and improving semiconductor component yields while dealing with rapidly changing semiconductor component designs requiring more manufacturing efficiency. These challenges dictate the need for both increased delivery rates and improved consistency of delivery for the lifetime of the ampoule or vaporizer assembly. One area that can improve the overall installed base of semiconductor processing is providing improved efficiencies in precursor material sublimation with vaporizer vessel designs that can be implemented in current installations to address some of these manufacturing, energy consumption and precursor sublimation efficiency challenges. Providing a retrofitable or configurable vaporizer assembly that can be readily used onsite would be a substantial advantage to the semiconductor manufacturer and advancement in the prior art.

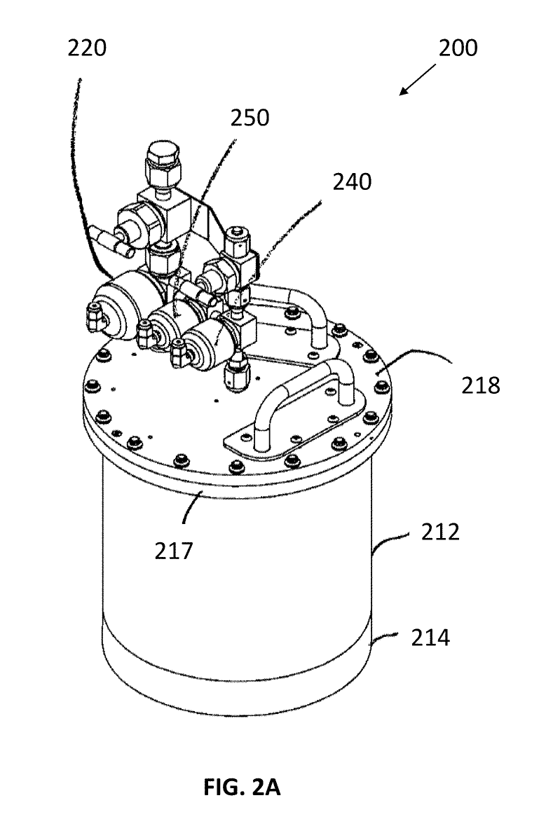

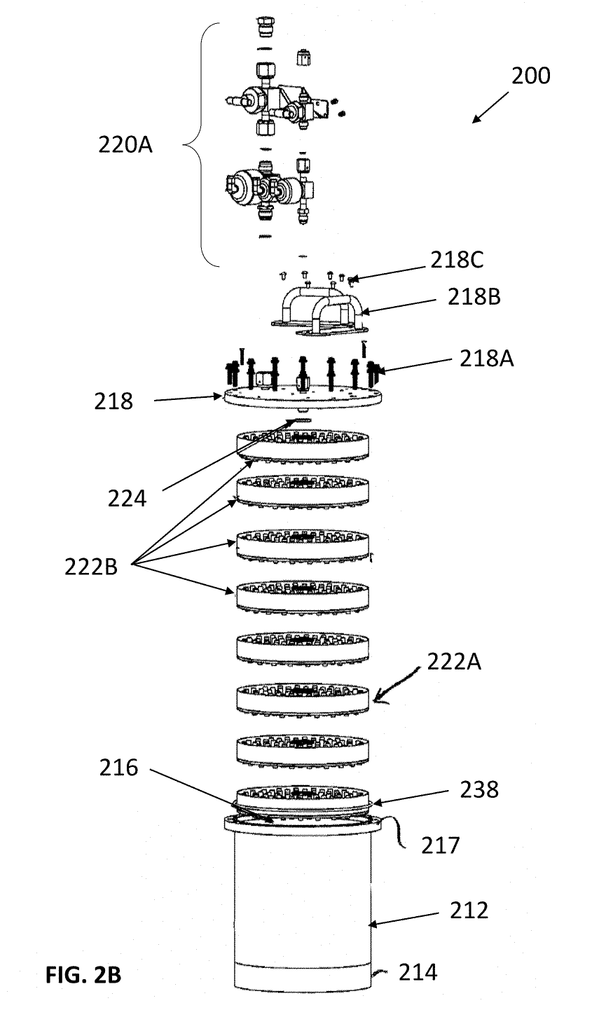

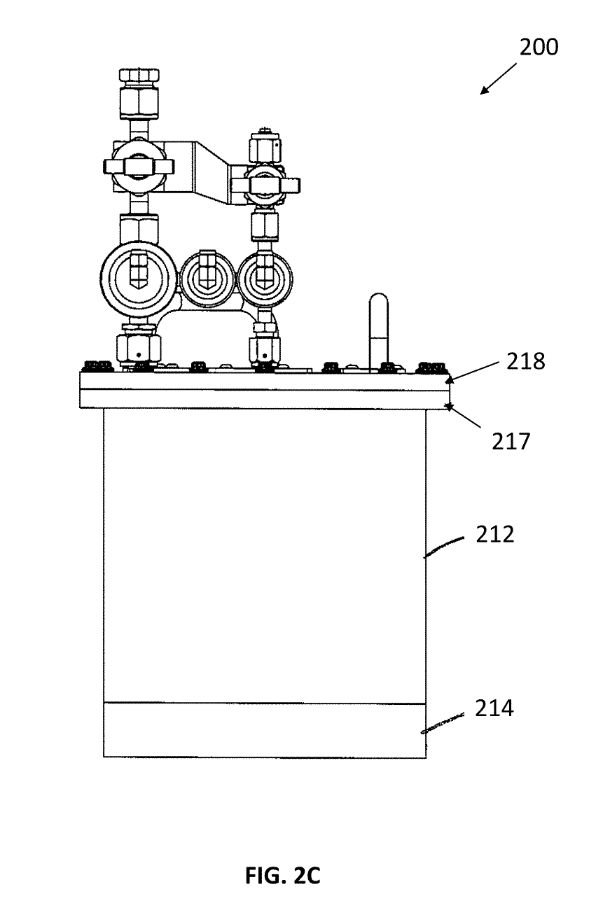

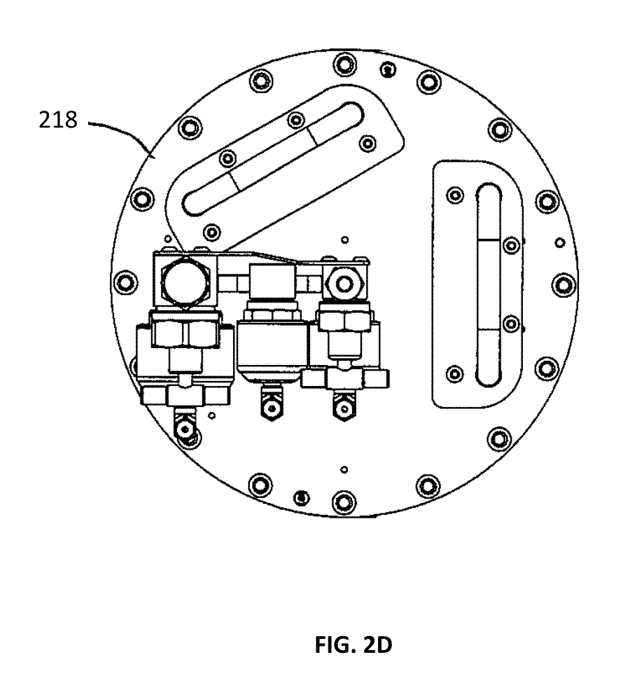

Referring now to one or more of the various embodiments of the invention that solve improved utilization rates and efficiencies for precursor materials as well as final product yields for the semiconductor manufacturer, there are provided vaporizer assemblies that can be retrofitted into current standard vaporizer vessels found in current installations. Referring now to FIGS. 2A-2D, there is illustrated a perspective view, an exploded view, a side view and a top view of a vaporizer vessel assembly 200, including a set of support trays 222 inside a vessel body or base assembly 212 according to an example embodiment of the invention, for vaporizing and delivering vaporized source material. Vessel assembly 200 includes a vessel body 212 having an interior volume defined by a sidewall 216, a vessel body rim opening 217 and an interior sidewall surface. The vaporizer assembly also includes a base member 214 disposed under and closing a bottom opening of first vessel body 212 and a lid member 218 disposed on rim opening 217 of the vessel body and a gas inlet 220 and a gas outlet 240 arranged in fluid communication with the interior volume of vessel body 212, gas inlet 220 configured to supply a first gas to the interior volume of vessel body 212.

In one example embodiment, the vessel body has a cylindrical shape machined to very close tolerances (e.g., in a range of 1/1000th to 3/1000th of an inch (25.4 μm to 76.2 μm). The vessel includes a lid 218 that fits over vessel body 212 and includes an interposing O-ring 238 to improve the seal between lid 218 and body 212. Lid 218 includes mounting hardware such bolts 218A, and handles 218B with associated screws 218C for moving the vessel. Lid 218 further includes mounted thereon a carrier gas inlet valve 220 (and carrier valve assembly 220A) arranged to selectively introduce carrier gas into the interior volume of the vessel, when the valve is open, and a gas outlet valve 240 for dispensing of the vaporized material from the vaporizer vessel and a bypass valve 250 for use of purging connections dry after installation and removing residual chemistry to remove the container after use. The bypass valve could also be used to cycle carrier gas flow between the container during deposition and the bypass between wafers. Vaporizer vessel body 212 can be constructed from materials similar to vessel bodies 12 and 112 described above.

In this example embodiment, vaporizer assembly 200 further includes a plurality of vented support trays 222 with tray circumferential sidewalls 216 disposed within the interior volume and in contact with interior diameter of vessel body 212, plurality of vented support trays 222 including a first set of trays 222A disposed within first vessel body 212 and under a second set of trays 222B that are disposed within vessel body 212. In this example embodiment, trays 222A and 222B have about the same sidewall height, the plurality of the support trays adapted to support a vaporizable source material in the flow path extending between the gas inlet and the gas outlet. In an another embodiment, first set of trays 222A have a first tray sidewall height greater than a second tray sidewall height of second set of trays 222B. The increased precursor material disposed within the first set of trays 222A due to the increased sidewall height (which has a greater container volume for the precursor material) promotes a more uniform utilization rate as the carrier gas passes from thorough a center carrier tube and up through trays 222. FIGS. 2C and 2D illustrate side and top views of vessel assembly 200 with associated dimensions particularly for the vessel body carrying support trays 222.

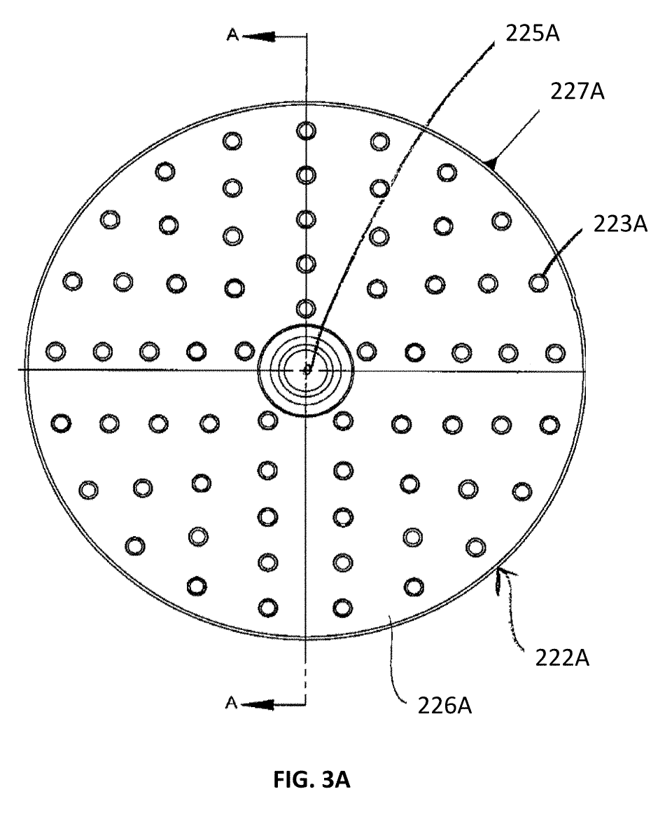

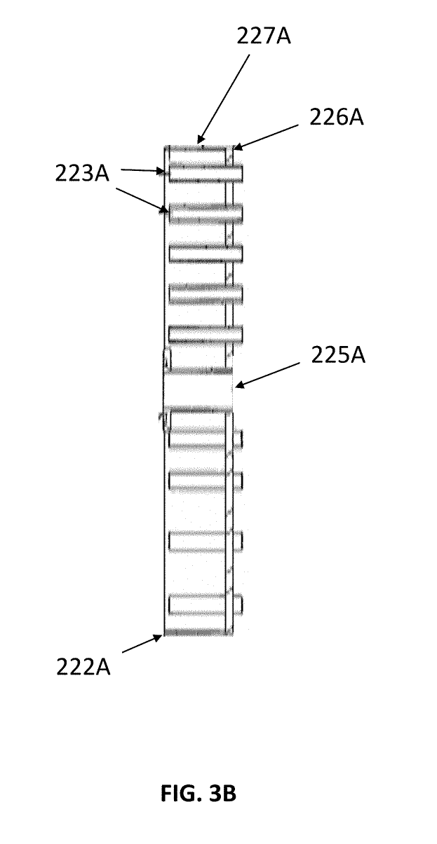

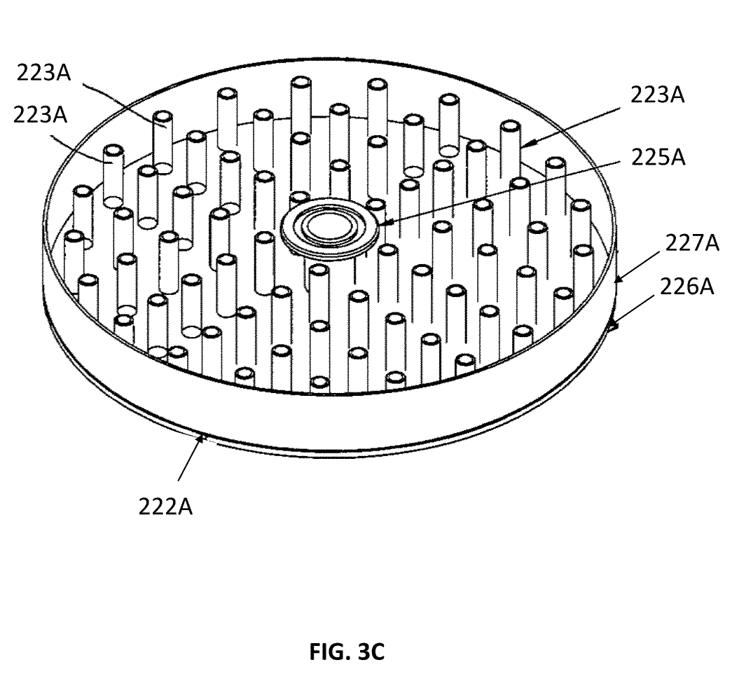

Referring now to FIGS. 3A-3C, there are illustrated top, side and perspective views of a support tray 222A for any of the vaporizer vessels described herein according to an example embodiment of the invention. In this example embodiment, support tray 222A includes a floor panel 226A (and a sidewall 227A) that supports the precursor material and includes a plurality of through-tubes 223A (or holes or elongate slots, depending on the vaporizer system) to facilitate the carrier gas to flow up through the various tray modules in the vessel or ampoule. In this example embodiment, sidewall 227A has a height of about 1.170 inches and through tubes 223A have a height above floor panel 226A of about 0.965 inches, being just below a surface of a horizontal plane of tray 222A. Through-tubes 223A in various embodiments extend upwardly from floor 226A of the support tray and define a central passageway 225A communicating with a corresponding opening or hole in tray floor 226A. In other embodiments, through-tubes 223A extend upwardly from floor 226A of the tray in the same manner, but also extend downwardly below tray 222A as illustrated in FIG. 3B, so that central passageway 225A can also be enclosed by a through-tube, e.g., as a central bore thereof, both above and below the floor of the tray. The through-tubes can have any shape or configuration that provides for flow of gas therethrough such as being cylindrical or conical in shape. In a related embodiment, the vessel body and trays use a central or main gas flow structure other than a central opening, such as along and down through a perimeter of the support trays and vessel body.

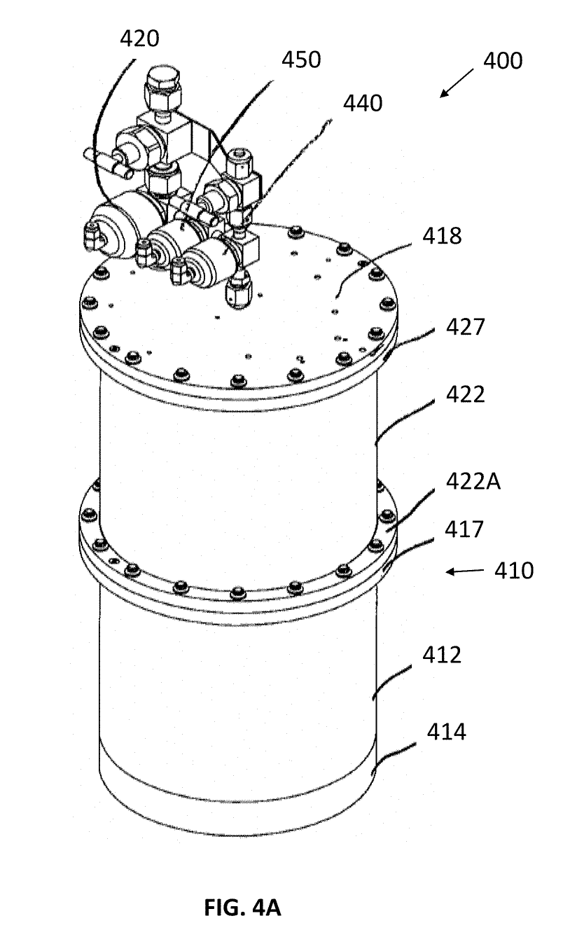

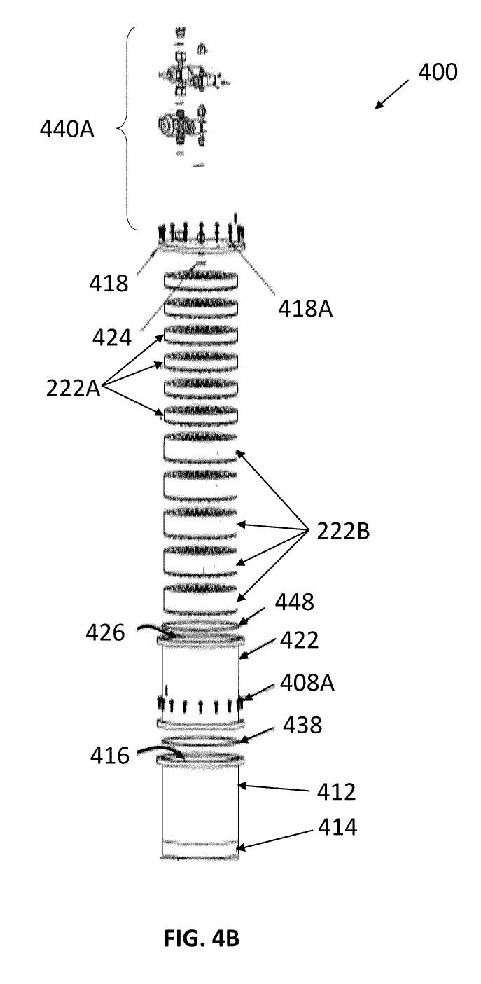

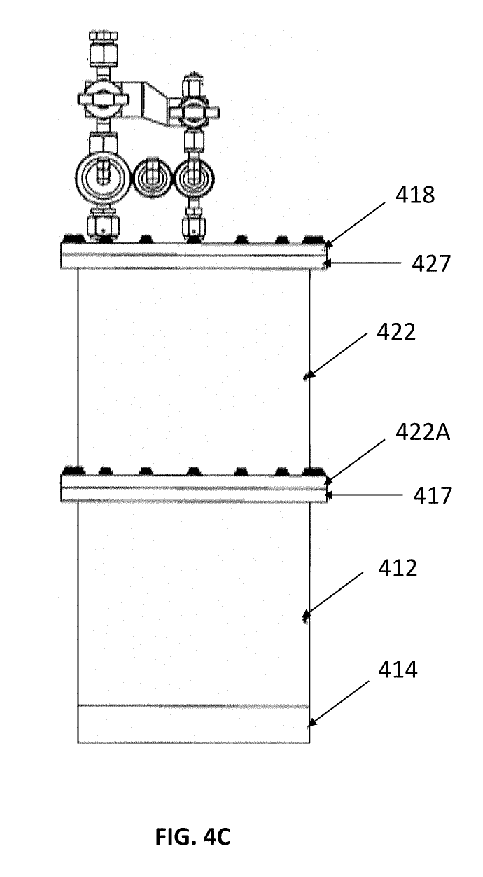

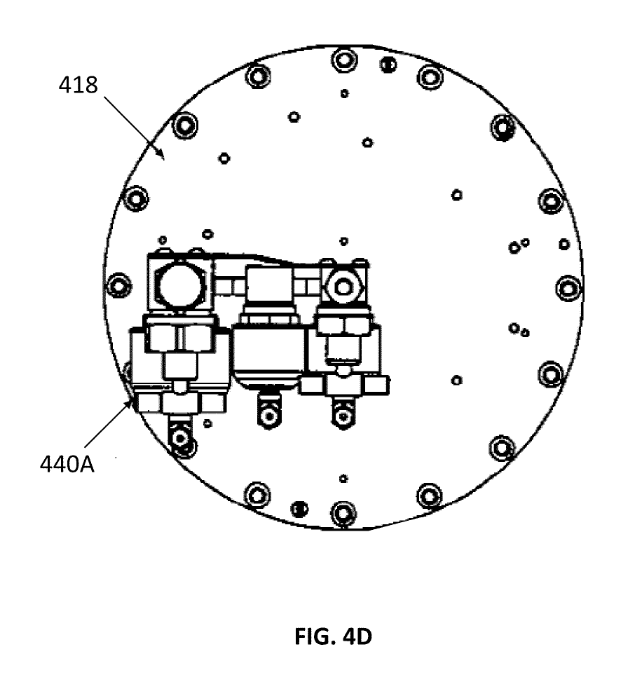

Referring now to FIGS. 4A-4D, there are illustrated a perspective view, an exploded view, a side view and a top view of a vaporizer vessel 400 including a set of support trays 222A and 222B inside a vessel body or base according to an example embodiment of the invention. Assembly 400 includes a multiple-vessel body assembly 410 including at least a first and a second longitudinally attached vessel bodies 412 and 422, respectively, having a common longitudinal axis and which define an interior volume of the multiple-vessel body assembly. Each of the vessel bodies has an interior volume 416 and 426, respectively, defined by a sidewall and a vessel body rim openings, 417 and 427, respectively, with each of the vessel bodies having an interior diameter of the vessel body and having an interior sidewall surface. In this example embodiment, vessel bodies 412 and 422 each have a cylindrical shape machined to very close tolerances (e.g., in a range of 1/1000th to 3/1000th of an inch (25.4 μm to 76.2 μm).

Vaporizer system 400 also includes a base member 414 disposed under and closing a bottom opening of first vessel body 412 and a lid member 418 disposed on rim opening 427 of second vessel body 422, second vessel body 422 having a bottom rim 422A disposed on rim opening 417 of first vessel body 412. Lid 418 which fits over vessel body 212 also includes an interposing O-ring 238 to improve the seal between lid 418 and body 412. Lid 418 also includes mounting hardware such bolts 418A (and may handles with associated screws for moving vessel 400). System 400 further includes a gas inlet 420 (and carrier valve assembly 420A) and a gas outlet 440 for dispensing of the vaporized material from the vaporizer vessel arranged in fluid communication with the interior volume of multiple-vessel body assembly, gas inlet 420 configured to supply a first gas to the interior volume of the multiple-vessel body assembly 410. Lid 418 further includes a bypass valve 250 for use of purging connections dry after installation and removing residual chemistry to remove the container after use. The bypass valve could also be used to cycle carrier gas flow between the container during deposition and the bypass between wafers. Vaporizer vessel bodies 412 and 422 can be constructed from materials similar to vessel bodies 12, 112 and 212 described above.

System 400 includes a plurality of vented support trays 222A and 222B with tray circumferential sidewalls disposed within the interior volume and in contact with interior diameter of multiple-vessel body assembly 410, the plurality of vented support trays including a first set of trays disposed 222B within first vessel body 412 and under a second set of trays 222A that are disposed within second vessel body 422, wherein each of the first set of trays 222B have a first tray sidewall height greater than a second tray sidewall height of second set of trays 222A, the plurality of the support trays designed to support a vaporizable source material in the flow path extending between gas inlet 420 and gas outlet 440. In this example embodiment, support trays 222B are designed purposely to be deeper or have a higher tray sidewall so as to support more vaporizable material than trays 222A so as to promote a more uniform vaporized material and thereby have a more uniform deposition of material on the substrates being manufactured. In addition, the additional material in trays 222B also increase manufacturing time per manufacturing run before the line has to be turned off to add more vaporizable materials to the support trays in vessel assembly 410. With this multiple vessel body assembly 410 and different sized support trays, utilization levels have increased to 90% from traditional utilization levels of around 50%. In this example embodiment, five larger support trays 222B are used with smaller support trays 222A. In other embodiments, the ratio is to have more of the larger trays 222B to smaller trays 222A, such as four to six larger trays 222B to two to four smaller trays 222A.

In a related embodiment, first vessel body 412 has a longitudinal height greater than the longitudinal height of second vessel body 422. In another embodiment, a first longitudinal height of first vessel body 412 is equal to the longitudinal height of second vessel body 422. In yet another related embodiment, second vessel body 422 includes a lower base rim configured to mate with the upper rim opening of the first vessel body. In another embodiment, the first tray sidewall height of trays 222B is less than the second tray sidewall height of trays 222A. In related example embodiment of a vaporizer system, a number of first set of support trays 222A equals the number of second set of support trays 222B. In another example embodiment, the number of first set of support trays 222A is greater than the number of second set of support trays 222B. In yet another example embodiment, the height of each of first set of support trays 222B is about 3 to about 4 times the height of each of second set of support trays 222A. In another example embodiment, the vaporizer assembly includes support trays that have an anti-corrosion coating selected from the group consisting of metal oxides, metal nitrides, metal carbides, and combinations of these films layered together.

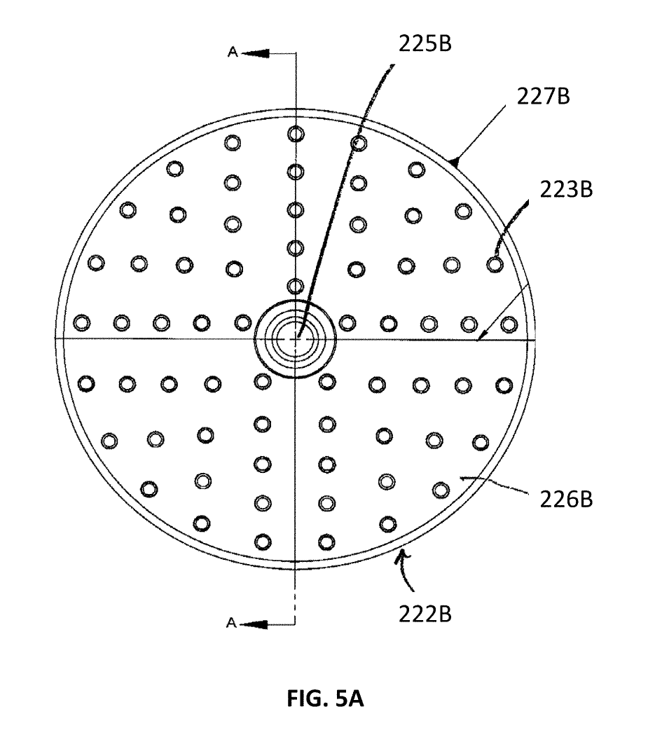

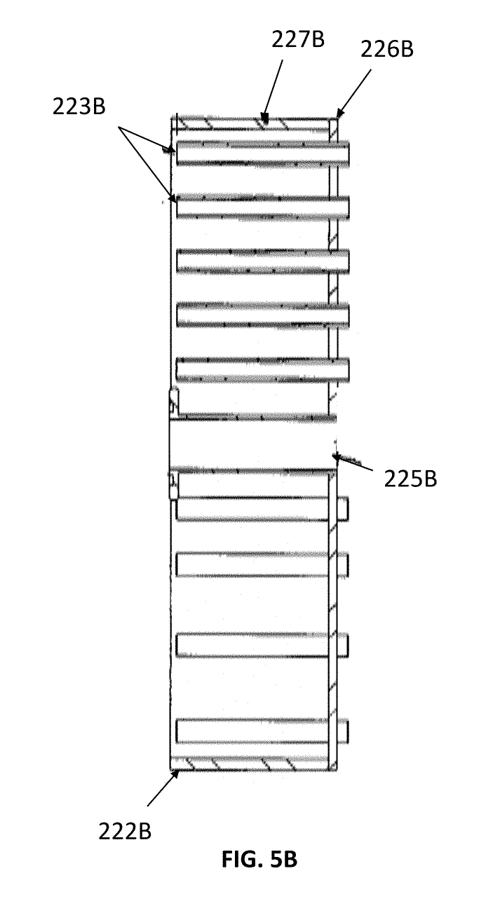

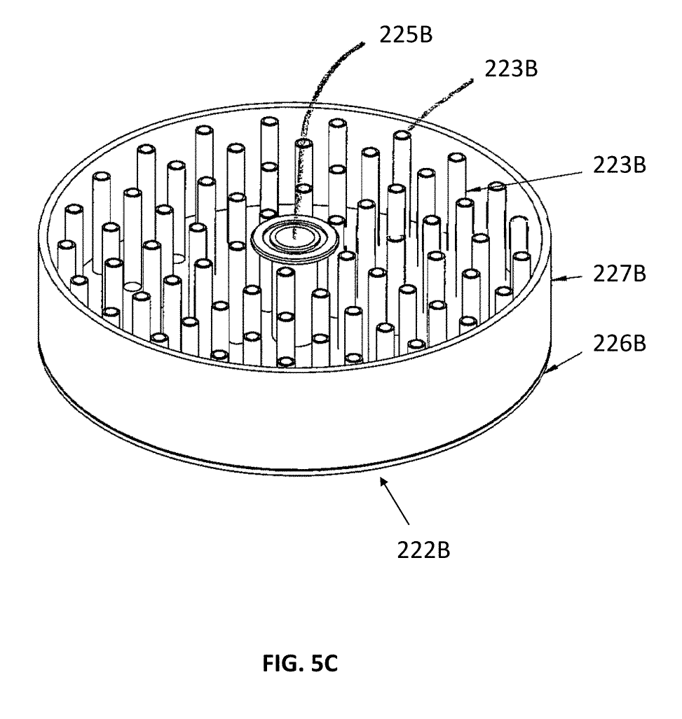

Referring now to FIGS. 5A-5C, there is illustrated top, side and perspective views of a support tray for any of the vaporizer vessels described herein according to an example embodiment of the invention. In this example embodiment, support tray 222B includes a floor panel 226B (and a sidewall 227B) that supports the precursor material and includes a plurality of through-tubes 223B (or holes or elongate slots, depending on the vaporizer system) to facilitate the carrier gas to flow up through the various tray modules in the vessel or ampoule. In this example embodiment, sidewall 227B has a height of about 2.355 inches and through tubes 223B have a height above floor panel 226B of about 2.150 inches, being just below a surface of a horizontal plane of tray 222B. Through-tubes 223B in various embodiments extend upwardly from floor 226B of the support tray and define a central passageway 225B communicating with a corresponding opening or hole in tray floor 226B. In other embodiments, through-tubes 223B extend upwardly from floor 226B of the tray in the same manner, but also extend downwardly below tray 222A as illustrated in FIG. 3B, so that central passageway 225B can also be enclosed by a through-tube, e.g., as a central bore thereof, both above and below the floor of the tray. The through-tubes can have any shape or configuration that provides for flow of gas therethrough such as being cylindrical or conical in shape. In a related embodiment, the vessel body and trays use a central or main gas flow structure other than a central opening, such as along and down through a perimeter of the support trays and vessel body.

Through-tubes 232A and 232B are secured to the floor of the tray in any suitable matter, e.g., by welding, brazing, mechanical fastener attachment, press-fit, swaging, etc. In the alternative, the through-tubes can be integrally formed as part of the tray floor. In a specific embodiment, the height of each of the through-tubes is approximately the same height as that of the tray sidewall, although other embodiments are contemplated, in which the height of each of the through-tubes is greater or less than such sidewall. The side walls of the respective trays may be of sufficient height, so that the trays are stackable to form a vertically extending stacked array in the interior volume of the vessel of the vaporizer.

The various support tray assemblies described herein can be subjected to standard vaporizer temperatures applied to standard vaporizer assemblies that are utilized in a given application, depending on the operating conditions of the downstream fluid-utilizing apparatus, e.g., CVD apparatus or ion implantation system, and the vapor pressure and the amount of the source material that is provided. In various specific embodiments in which sublimable solid source reagents are utilized, vaporizer temperatures in a range of from about 20° C. to about 300°C. can be utilized (current applications may be limited by the availability of high purity valves that go above 300° C.). Implementations of the present invention involving metal halide solid source reagents can for example utilize temperatures in a range of from about 100° C. to about 200° C., in specific embodiments. The source reagent material may be in any suitable form, including solid form, liquid form, semi-solid form, or a solution containing the source reagent material dissolved or dispersed in a suitable solvent medium. For additional chemistries for sublimation, tray module configurations, gas flows and ampoule assembly configurations, reference is made to U.S. Pat. No. 8, 821,640 to Cleary et al., and to WO 2015/164029 to Baum et al., published on Oct. 29, 2015 and entitled SOLID VAPORIZER which is incorporated by reference in its entirety.

Various embodiments of the invention have been described above for purposes of illustrating the details thereof and to enable one of ordinary skill in the art to make and use the invention. The details and features of the disclosed embodiment[s] are not intended to be limiting, as many variations and modifications will be readily apparent to those of skill in the art. Accordingly, the scope of the present disclosure is intended to be interpreted broadly and to include all variations and modifications coming within the scope and spirit of the appended claims and their legal equivalents.

What is claimed is:

1. A vaporizer assembly for vaporizing and delivering vaporized source material, the vaporizer assembly comprising:
a multiple-vessel body assembly including at least a first and a second longitudinally attached vessel bodies having a common longitudinal axis and which define an interior volume of the multiple-vessel body assembly, each of the vessel bodies having an interior volume defined by a sidewall and a vessel body rim opening, each of the vessel bodies having an interior diameter of the vessel body and having an interior sidewall surface;
a base member disposed under and closing a bottom opening of the first vessel body;
a lid member disposed on the rim opening of the second vessel body, the second vessel body disposed on the rim opening of the first vessel body;
a gas inlet and a gas outlet arranged in fluid communication with the interior volume of the multiple-vessel body assembly, the gas inlet being adapted to supply a first gas to the interior volume of the multiple-vessel body assembly; and
a plurality of vented support trays with tray circumferential sidewalls disposed within the interior volume and in contact with interior diameter of the multiple-vessel body assembly, the plurality of vented support trays including a first set of trays disposed within the first vessel body and under a second set of trays that are disposed within the second vessel body, wherein each of the first set of trays have a first tray sidewall height greater than a second tray sidewall height of the second set of trays, the plurality of the support trays adapted to support a vaporizable source material in the flow path extending between the gas inlet and the gas outlet.

2. The vaporizer assembly of claim 1, wherein the first vessel body has a longitudinal height greater than the longitudinal height of the second vessel body.

3. The vaporizer assembly of claim 1, wherein a first longitudinal height of the first vessel body is equal to the longitudinal height of the second vessel body.

4. The vaporizer assembly of claim 1, wherein the second vessel body includes a lower base rim configured to mate with the upper rim opening of the first vessel body.

5. The vaporizer assembly of claim 1, wherein the first tray sidewall height is less than the second tray sidewall height.

6. A vaporizer assembly for vaporizing and delivering vaporized source material, the vaporizer assembly comprising:
a vessel body having an interior volume defined by a sidewall and a vessel body rim opening;
a base member disposed under and closing a bottom opening of the vessel body;
a lid member disposed on the rim opening of the vessel body;
a gas inlet and a gas outlet arranged in fluid communication with the interior volume of the vessel body, the gas inlet being adapted to supply a first gas to the interior volume of the vessel body; and
a plurality of vented support trays with tray circumferential sidewalls disposed within the interior volume and in contact with interior diameter of the vessel body, the plurality of vented support trays including a first set of trays disposed within the first vessel body, the plurality of the support trays adapted to support a vaporizable source material in the flow path extending between the gas inlet and the gas outlet, wherein at least one support tray disposed near the base member includes an O-ring disposed about an outer surface of the at least one support tray.

7. The vaporizer assembly of claim 6, wherein the plurality of support trays includes a second set of trays that are disposed within the vessel body above the first set of trays, each of the first set of trays having a first tray sidewall height greater than a second tray sidewall height of the second set of trays.

8. The vaporizer assembly of claim 7, wherein a number of the first set of support trays equals the number of the second set of support trays.

9. The vaporizer assembly of claim 7, wherein a number of first set of support trays is greater than the number of the second set of support trays.

10. The vaporizer assembly of claim 7, wherein the height of each of the first set of support trays is about 3 to about 4 times the height of each of the second set of support trays.

11. The vaporizer assembly of claim 6, wherein each of the support trays includes an anti -corrosion coating selected from the group consisting of metal oxides, metal nitrides, metal carbides, and combinations of these films layered together.

12. The vaporizer assembly of claim 11, wherein the anti-corrosion layer of metal oxide is aluminum oxide.

13. The vaporizer assembly of claim 11, wherein the anti-corrosion layer of metal nitride is aluminum nitride.

14. The vaporizer assembly of claim 11, wherein the anti-corrosion layer of metal oxide is silicon dioxide.

15. A vaporizer assembly for vaporizing and delivering vaporized source material, the vaporizer assembly comprising:
a vessel body having an interior volume defined by a sidewall, a vessel body rim opening and an interior sidewall surface;
a base member disposed under and closing a bottom opening of the first vessel body;
a lid member disposed on the rim opening of the vessel body;
a gas inlet and a gas outlet arranged in fluid communication with the interior volume of the vessel body, the gas inlet being adapted to supply a first gas to the interior volume of the vessel body; and
a plurality of vented support trays with tray circumferential sidewalls disposed within the interior volume and in contact with interior diameter of the vessel body, the plurality of vented support trays including a first set of trays disposed within the first vessel body and under a second set of rays that are disposed within the vessel body, wherein each of the first set of trays have a first tray sidewall height greater than a second tray sidewall height of the second set of trays, the plurality of the support trays adapted to support a vaporizable source material in the flow path extending between the gas inlet and the gas outlet.

16. The vaporizer assembly of claim 15, wherein a number of the first set of support trays equals the number of the second set of support trays.

17. The vaporizer assembly of claim 15, wherein a number of first set of support trays is greater than the number of the second set of support trays.

18. The vaporizer assembly of claim 15, wherein the height of each of the first set of support trays is about 3 to about 4 times the height of each of the second set of support trays.

19. The vaporizer assembly of claim 15, wherein each of the support trays includes an anti -corrosion coating selected from the group consisting of metal oxide, metal nitride metal carbide and combinations of these coatings in a layered structure.

20. The vapor delivery vessel of clam 19, wherein the anti-corrosion layer of metal oxide is aluminum oxide or silicon dioxide.
